(19) United States
(12) Patent Application Publication
(10) Pub. No.: US 2010/0045212 A1
(43) Pub. Date: Feb. 25, 2010

(54) Devices having laterally arranged nanotubes

(76) Inventor: Vladimir Mancevski, Austin, TX (US)

Correspondence Address: Xidex Corporation, Suite 703, 8906 Wall Street, Austin, TX, 78754, US

(21) Appl. No.: 12/456,877

(22) Filed: Jun. 24, 2009

Related U.S. Application Data
(60) Provisional application No. 61/133,021, filed on Jun. 25, 2008.

(51) Int. Cl. H05B 43/00; H01J 1/02; H05K 1/09

(52) U.S. Cl. 315/326; 313/309; 174/257; 977/734

(57) ABSTRACT

Nanotubes are positioned laterally between posts. These posts can be formed directly on a substrate, or on top of sharp protrusions, which are themselves located on the substrate. Horizontally positioned nanotubes can be used as emitters, either singly or as part of an array. Electron emissions from the sidewalls of the nanotubes can be used to generate X-rays, Microwaves and Terahertz radiation, or other electromagnetic radiation. Arrays of laterally positioned nanotubes can reduce screening effects and other emission irregularities sometimes caused by vertically positioned nanotube emitters that rely on emissions from nanotube ends. Carbon nanotubes can be manually between two posts, or grown in place.

### RELATED APPLICATIONS

This application claims the benefit of U.S. Provisional Application 61/133,021, filed on Jun. 25, 2008, and entitled “Lateral Carbon Nanotube Emitter”

### FIELD

The present disclosure relates generally to carbon nanotubes, and more particularly to laterally arranged carbon nanotubes.

### BACKGROUND

There has been significant effort during the past several years to build microwave vacuum electron devices using cold cathodes to replace the existing hot thermionic cathodes. The most common approach has been the use of Spindt type field emission array (FEA) cathodes. However this approach has failed to produce practical, useful devices to date.

Another approach to constructing vacuum electron devices includes vertically arranged carbon nanotubes (CNT). CNT emitters can achieve more than 10 μA of current from a single emitter tip, and can be packaged into arrays with anywhere from 1 million to 100 million tips/cm². Thus far, however, emission non-uniformity has prevented such field emission arrays from achieving large total currents (>1 Amp).

Prior research has shown that individual, vertically aligned CNTs, as opposed to CNT bundles and films, exhibit low turn-on voltage (1 V/μm), high emission current (0.2 mA), and corresponding high emission current density (4×10⁸ A/cm²). However, as a result of electrostatic screening effects, the high emission currents from an individual emitter may not translate directly to an equivalent emission current from a large sample containing many such emitters. This is true whether the emitter is CNT based or metal based. This is also true for any array elements comprising individual, bundle, or film form-factors.

Furthermore, any length non-uniformities among vertically aligned CNTs in an array of vertically arranged CNTs, can result in non-uniform field emissions, leading to hot-spots, possible overheating, and self destruction of the CNTs.

### SUMMARY

A device according to various embodiments includes a substrate having multiple protrusions formed on one of its surfaces. Posts are formed on the protrusions, and at least one nanotube is laterally connected between two of the posts. In some embodiments, a pre-grown nanotube can be manually positioned on the posts and electron-beam welded into place. In other embodiments, the nanotube is grown laterally between the posts. Some devices include an array of laterally positioned nanotubes.

In various embodiments, the end portion of the protrusion, on which the posts are formed, is less than about 10 microns wide, and the posts are spaced less than about 10 microns apart. The posts in at least one embodiment are less than about 5 microns high. The posts can be deposited using a semiconductor fabrication process. In some instances, the protrusion is a wire, and the posts are the edges remaining after a center portion of a wire's end has been removed.

Devices according to some embodiments are emission devices, which can include two electrodes, such as an anode and a cathode. One of the electrodes includes at least one nanotube laterally connected between posts. These posts can be formed on protrusions, or directly on a substrate. The emission device can be configured to emit electrons primarily from a sidewall of the at least one nanotube. In some such embodiments, an electrode including a laterally connected nanotube can be used as a cold cathode, and can be used in various configurations to generate X-rays. An emission device can also be configured to include a gate, a bunching electrode, a resonant cavity, and a waveguide for generating Microwave and Terahertz radiation if desired.

A method according to the present disclosure can include connecting a CNT to an electron beam emitting device, so that a sidewall of the CNT serves as an electrode; and activating the electrode by applying a voltage to the CNT. An array of lateral CNTs can also be used as an electrode. In some embodiments, the CNT is used as an anode of the electron beam emitting device, which in some embodiments includes a vacuum chamber.

### BRIEF DESCRIPTION OF THE DRAWINGS

Aspects of this disclosure will become apparent upon reading the following detailed description and upon reference to the accompanying drawings, in which like references may indicate similar elements:

FIG. 1 is a combination block and schematic diagram of a side view of a device including a nanotube laterally connected between two posts, according to embodiments of the present disclosure;

FIG. 2 is a combination block and schematic diagram of an end view of device including an array of laterally positioned nanotubes and a gate structure, according to embodiments of the present disclosure;

FIG. 3 is a diagram illustrating an emission device configured to produce Terahertz rays according to an embodiment of the present disclosure;

FIG. 4 is a diagram showing an array of laterally positioned nanotubes positioned on top of sharp posts located on protrusions formed on a surface of a substrate, according to embodiments of the present disclosure;

FIG. 5 is a diagram showing an array of laterally positioned nanotubes on knife-edge posts that can be included as part of an emission device according to embodiments of the present disclosure;

FIG. 6 is a photograph of two posts formed by removing material from the center-end of a Tungsten wire, according to embodiments of the present disclosure;

FIG. 7 is a photograph of two posts, deposited using electron beam based chemical vapor deposition, near the top of a sharp protrusion, according to embodiments of the present disclosure;

FIG. 8 is a diagram showing various stages in the formation of posts used for growing laterally positioned nanotubes according to embodiments of the present disclosure;

FIG. 9 is a diagram illustrating that the size and pitch of posts can be varied according to embodiments of the present disclosure;

FIG. 10 is a photograph of a pre-grown carbon nanotube laterally positioned between two posts, according to embodiments of the present disclosure;

FIG. 11 is a close-up photograph of one end of the carbon nanotube illustrated in FIG. 10, showing an end of the carbon nanotube welded to a post, in accordance with various embodiments of the present invention.

### DETAILED DESCRIPTION

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

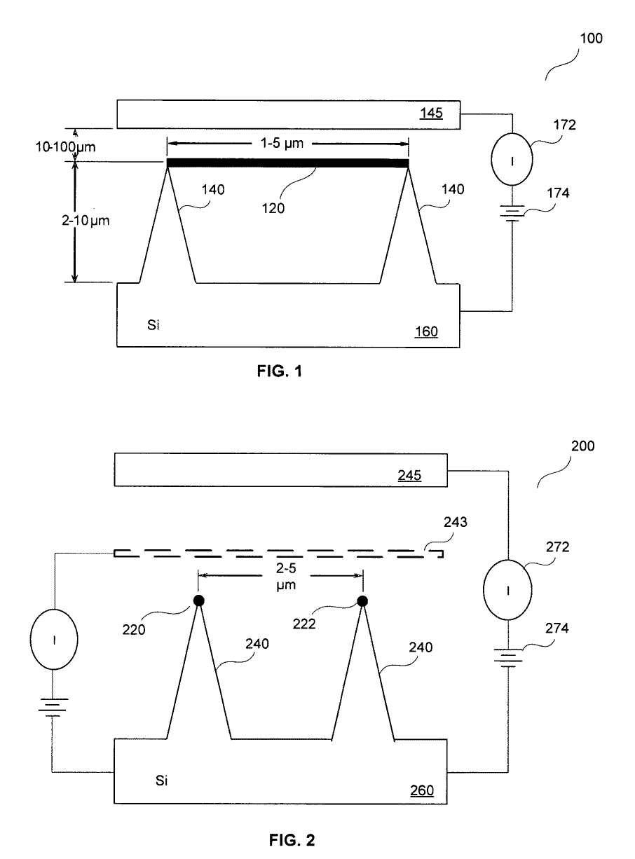

Referring first to FIG. 1, an electron emission device 100 will be discussed according to various embodiments of the present disclosure. Electron emission device 100 includes a laterally positioned nanotube 120 connected to two posts 140 formed on a substrate 160. Nanotube 120, in at least one embodiment, serves as an electrode, and is positioned horizontally with respect to another electrode, such as anode 145.

In the illustrated example, nanotube 120 is connected as a cathode, with electrode 145 serving as an anode. In various embodiments, electrode 145 can be constructed of, or coated with, copper (Cu), Tungsten (W), or another material consistent with a manner in which emission device 100 is to be used. A source, modeled as current source 172 and voltage source 174, is connected between anode 145 and substrate 160. In operation, the voltage applied to substrate 160 provides a voltage potential to the nanotube 120 which in turn emits electrons from a sidewall that is positioned horizontally to anode 145. In many embodiments, posts 140 are electrically isolated from each other until nanotube 120 is connected between them. In various embodiments, nanotube 120 is a carbon nanotube, and can function as a cold cathode in various devices, such as vacuum devices, x-ray emitters, terahertz emitters, as a pixel elements in various displays, or otherwise.

It may be noted that electrons might be emitted from the ends of nanotube 120 in addition to being emitted from a sidewall of nanotube 120. Various embodiments of the present disclosure are directed towards methods and apparatus that make use primarily of electron emissions from the sidewalls of nanotube 120.

Nanotube 120 can have a diameter of between about 1 nm and 50 nm. In some embodiments, nanotube 120 is less than about 20 nm in other embodiments, nanotube having diameters of less than 10 nm are used, including single walled nanotubes, which are about 1 nm in diameter.

As illustrated in FIG. 1, the spacing between posts 140 can be between about 1 in 5 μm. In some embodiments post spacing of between 500 nm and 10 μm is used. Particular embodiments employ post spacing of less than about 10 μm, less than 5 μm, or less than 1 μm. As illustrated in FIG. 1, posts 140 are between about 2 and 10 μm high. In other embodiments, however, posts 140 can be less than approximately 500 nm, 1 μm, 5 μm, or 10 μm.

The spacing between laterally positioned nanotube 120 and anode 145, as illustrated, is between about 10-100 μm. This distance may be varied as desired depending on the particular application in which device 100 is used. Furthermore, although not illustrated in FIG. 1, a gate electrode can be inserted between nanotube 120 and anode 145, to control the emission current from nanotube 120.

Referring next to FIG. 2, an emission device 200 including an array of laterally positioned nanotubes and a gate structure 243 is discussed according to various embodiments of the present disclosure. FIG. 2 illustrates an end view of nanotubes 220 and 222, each of which are connected to one of the posts 240, and to another post (not illustrated). Posts 240 are located on substrate 260, which is in turn connected to electrode 245 via current source 272 and voltage source 274. An array of laterally positioned nanotubes, such as nanotubes 220 and 222, can be used as an electrode in various emission devices, some of which can include a gate structure 243.

When a voltage is applied to either or both nanotubes 220 and 222, electrons emitted from the nanotubes' sidewalls can travel to electrode 245. A gate structure 243, which in the illustrated embodiment is coupled to a source, can be used to regulate the flow of electrons from the array of nanotubes to electrode 245. In some embodiments, gate structure 243 can be used to extract electrons from the array of nanotubes.

In various embodiments, elements of an array, for example nanotubes 220 and 222, can be powered as a unit, or individually. Powering all of the lateral nanotubes in an array at the same time can be performed using a collection of addressable or non-addressable conductive lines coupling the array elements, for example nanotubes 220 and 222, to one or more power sources or control electronics. In some instances, the connections can be hardwired, so that whenever the source is activated, a voltage is applied to nanotubes 220 and 222.

In other embodiments, one or more of the conductive lines can be switched to enable power to be selectively applied to particular array elements. In such embodiments, various switching or control schemes can be used to implement the selective enablement of array elements. For example, when an array of laterally arranged nanotubes is used to implement a display device, with each emission element serving as a pixel, conductive lines can be arranged in rows and columns, with the rows coupled to anodes and the columns coupled to cathodes, or vice-versa. In such an implementation, a particular pixel would be turned on when power is connected to both the anode and the cathode.

In various embodiments, nanotubes 220 and 222 are carbon nanotubes (CNTs), and form a field emission array (FEA), which can be used in high total current and high current density applications, such as microwave vacuum amplifiers and X-ray sources. As illustrated in FIG. 2, a CNT FEA can be formed on a substrate, and can include one or more CNT emitter elements configured to operate as a cold cathode. The CNT emitters are aligned horizontally to a surface of the substrate, and electron emission occurs primarily from the sidewalls of carbon nanotubes 220 and 222, as opposed to conventional emission from the end of the carbon nanotube. In the illustrated embodiment, CNTs 220 and 222 are substantially parallel to electrode 245, which can be configured as an anode to receive electrons emitted from the sidewalls of CNTs 220 and 222 In other embodiments, for example in some implementations of an X-ray source, electrode 245 is positioned at an angle to the laterally positioned CNTs 220 and 222, where electrode 245 can be a target plate configured to emit X-rays when struck by electrons emitted from the sidewalls of nanotubes 220 and 222.

Laterally positioned nanotubes, including arrays of laterally positioned CNTs disclosed herein, are well suited for some such applications, because they can reduce or eliminate the need for hot thermionic cathodes, which have slower response times and frequently use an external heating source. It is anticipated that various embodiments of laterally arranged CNT FEAs will be able to produce field emission currents of 1 Amp and greater, and produce current densities of 10 A/cm² and greater. Such current magnitudes and densities can be employed in microwave devices suitable for radar and communications, high power microwave devices for directed energy applications, medical x-ray sources, ionization/neutralization sources for spacecraft propulsion, and flat-panel field emission displays.

Laterally arranged nanotubes can be manufactured using a scaleable fabrication process that includes growing individual, non-bundled, horizontally aligned nanotubes suspended directly on a template of tall silicon posts formed on a substrate. In some embodiments the posts are formed of a material other than silicon, for example silicon dioxide or another suitable material or combination of materials.

In at least one embodiment, laterally arranged CNT FEAs are configured so that the emitter-to-emitter distance is balanced with respect to the length of the CNT and height of the posts. Such a balanced array can be used to achieve large emission currents by fabricating the array to include distributed nanotube elements placed to reduce or eliminate screening effects caused by adjacent or nearby CNTs.

In addition to reducing screening effects, electron emissions occurring from the sidewall of nanotubes, like those generated by the array of horizontally aligned nanotubes illustrated in FIG. 2, can help minimize various problems that might otherwise arise from manufacturing defects and imperfections in vertically aligned CNTs, such as height variation and the occurrence of open ended nanotubes, which can make CNTs more susceptible to burnout. For example, in at least one embodiment, each of the CNTs in an array tends to lie in the same plane, without any protrusions. This arrangement can reduce or eliminate the effects of non-uniformities among the nanotube emitters. A lateral CNT array as described herein can be fabricated so that CNTs are suspended on an array of conical or cylindrical silicon posts, where the spacing of the posts, the lengths of the CNTs, and the nanotube-to-nanotube emitter spacing can all be controlled.

In some embodiments, the array of nanotubes including nanotubes 220 and 222 can be used to produce thermionic emissions. In some embodiments, the array of nanotubes including nanotubes 220 and 222 can be used to produce a display pixel, or be used as a sensor in various applications. Furthermore, nanotubes 220 and 222 can be coated with a low work function material for use in even more applications.

Both nanotubes 220 and 222 are laterally positioned above substrate 260 at substantially the same height. In this way, undesirable fluctuations in electron emissions can be reduced. In some embodiments, nanotubes 220 and 222 are each connected at one end to a post 240, and to an additional post, not illustrated. The spacing between posts 240, as illustrated in FIG. 2, is 2-5 μm. In other embodiments, the spacing between posts 240 can be similar to the spacing between posts 140, as previously discussed in FIG. 1.

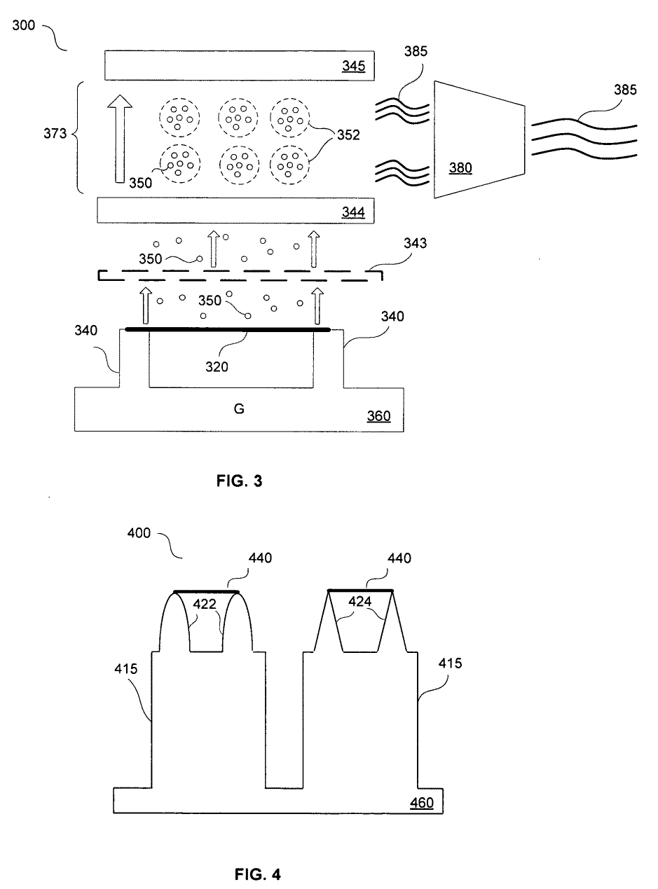

Referring next to FIG. 3, a schematic of a Terahertz ray emission device (TR device) 300 is discussed according to embodiments of the present disclosure. TR device 300 includes at least one laterally positioned nanotube 320 connected to posts 340, which are in turn formed on substrate 360. Nanotube 320, in this example, functions as a cold cathode. TR device 300 also includes anode 345; gate 343, which can control the flow of electrons 350 leaving nanotube 320; bunching electrode 344, which can be used to deliver electrons to anode 345 in bunches 352; and waveguide 380, which couples to resonant cavity 373 to guide Terahertz rays 385 produced as electron bunches 352 travel in a resonant cavity 373.

In various embodiments, the positions of gate 343, bunching electrode 344, anode 345, and other components of TR device 300 can be configured to produce electromagnetic energy of various frequencies and intensities, as desired. Furthermore, rather than using a single nanotube 320 as an emitter, an array of laterally positioned nanotubes, supported on posts, knife edge structures, protrusions, or a combination of these, can be used to implement TR device 300, or another emission device.

Referring next to FIG. 4, embodiments of the present disclosure employing posts positioned on top of protrusions formed on a substrate 460 will be discussed. An array 400 of nanotubes 440 can be laterally positioned on top of posts 422 in 424, which are in turn positioned on top of protrusions 415. In at least one embodiment, protrusions 415 are formed on top of MEMS substrate 460. In various embodiments, the spacing between posts 422 and posts 424 is less than 10 μm. Furthermore, protrusions 415 may each be considered to be “sharp,” which as used herein generally refers the protrusions having a high aspect ratio; in some embodiments an upper portion of the protrusion has a width less than about 10 μm wide. The width of the protrusions on which posts 422 and 424 are positioned can, in some implementations, have a measurable effect on fields generated from the sidewalls of the nanotubes 440.

Posts 422 and 424 may have various shapes, and be formed using various different methodologies. In at least one embodiment, post 422 and 424 can be formed using various semiconductor processes, including using various patterning and etching methods. Likewise, protrusions 415 can be formed on substrate 460 using various different mechanical, chemical, or other methods. For example, protrusions 415 can be formed by attaching a material to substrate 460, such as a wire. In other embodiments, protrusions 415 can be patterned and etched into substrate 460.

In at least one embodiment, power can be selectively applied to each of the nanotubes 440 individually or together. For example, addressable switching can be used to connect power to one or both of the nanotubes 440 when an appropriate control signal is applied to the switching element (not illustrated). In other embodiments, non-addressable arrays can be used. Various techniques for implementing addressable and non-addressable arrays can be implemented as desired, consistent with the present disclosure.

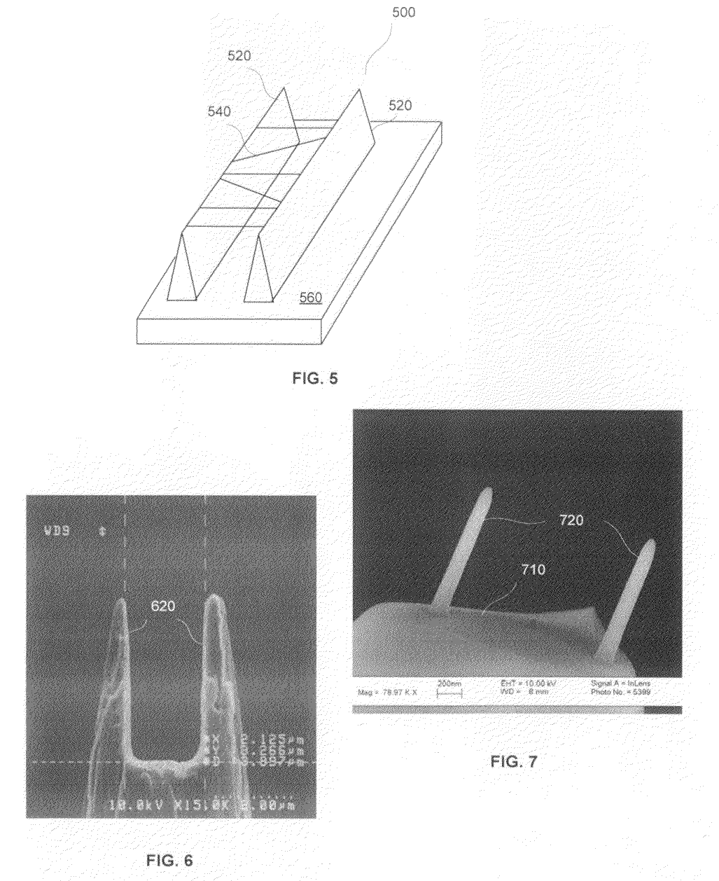

Referring next to FIG. 5, an embodiment of the present disclosure including an array 400 of nanotubes that form part of an emitting device according to various embodiments of the present disclosure. The array of nanotubes 540 are laterally connected to a plurality of knife edge structures 520, which are in turn positioned on substrate 560. Array 500 includes multiple nanotubes laterally positioned above substrate 560, and configured to produce electron emissions primarily from the sidewalls of nanotubes 540. Multiple nanotubes 540 are connected between the two knife edge structures, such that the nanotubes making up the array are each positioned in substantially the same plane with each other.

CNTs arranged according to the present disclosure provide various benefits over other emitter types, including but not limited to, small (nanometer-scale) dimensions, high aspect ratio, chemical inertness, improved electrical properties, and mechanical strength. For example, CNTs are far more resistant to sputtering from ionized residual gas molecules than conventional field emission cathodes composed of refractory metals, and CNTs are inert with respect to many residual gasses.

At least one embodiment of a lateral nanotube emitter has been constructed and tested to determine its emission properties. Results of the test show that field emission from a lateral CNT emitter element is comparable to emission from the end of a carbon nanotube, as shown in Table 1. As expected, because of their larger cross section (10 nm×2000 nm), the lateral emitters have smaller current density J, and larger electron beam spread dΩ. Therefore the resulting reduced angular current density Iᵣ′ and the reduced brightness Bᵣ are smaller for a lateral field emitter. However, the lateral emitter could reach higher maximum emission current than the vertical emitters. A vertical field emitter was run for 12 hour at 8.6 μA, as shown in FIG. 1, without CNT failure. The emission noises were compatible. The maximum emission current we could demonstrate was limited by the power supply we used and the tip-anode gap we have selected

TABLE 1

| | Max | | | Reduc. | | |
|---|---|---|---|---|---|---|
| | Emission | Emission | E-Beam | Angul. I | | Reduced |
| | Current | Current | Spread | Density | | Brightness |
| Emission | Iₘₐₓ | Noise | dΩ | Iᵣ′ | I Density J | Bᵣ (Rν) |
| Comparison | (nA) | (%) | (sr) | (nA sr⁻¹ V⁻¹) | (A cm⁻²) | (A m⁻² sr⁻¹ V⁻¹) |
| Vertical Tip | 1218 | 5.4 | 0.112 | 50.3 | 1.6 × 10⁶ | 2.7 × 10⁹ |
| Lateral Tip | 3893 | 4.5 | 0.810 | 11.9 | 2.4 × 10⁴ | 1.2 × 10⁸ |

Larger arrays of lateral CNT emitters can have various element densities. For example, various embodiments can have element densities of 10⁶-10⁷ nanotubes/cm², where most of the CNTs are suspended substantially horizontally on tall Si posts. Consider for example, an array of silicon posts with 3 μm post spacing and an active area of 2×2 mm. In such a case, the post density would be 10⁷ tips/cm². Such an array of lateral CNT emitters could produce current densities of between about 28 A/cm² to 56 A/cm², depending on the emitter fabrication yield.

For example, an assumption can be made that each horizontally aligned CNT emitter produces emission current of 5 μA. When screening effects of neighboring CNT element are accounted for, the array current density can be computed as follows: For a sample with tip density of 10⁷ emitters/cm² (3 μm tip spacing) a current density of about 56 A/cm² could be achieved if the field emitter fabrication yield were 100%. A current density of about and 28 A/cm² can be expected for a 50% yield in field emitter fabrication. Generally, a 50%-80% yield in field emitter fabrication is expected.

Continuing with the previous example, for a field emitter array area of 2 mm on a side, the total field emission current could be about 1 Å per field emitter array device. This level of current density can be very useful in applications, and such arrays could be used, for example, as sources for an X-ray or microwave vacuum electronics. In some embodiments, depending on the fabrication yield, the screening effects, and the emission current per single emitter, the emitter spacing can be decreased to increase the emitter density. This decrease in emitter spacing can, in some cases, cause an unwanted increase in the screening effect, and could lead to a reduction of the emission current.

Referring next to FIGS. 6 and 7, the fabrication of lateral CNT emitter arrays will be discussed according to embodiments of the present disclosure. Lateral CNT emitters can be constructed on a substrate by welding a CNT to the substrate, or by growing the CNT on the substrate. In some embodiments, the substrate includes a pair of high aspect ratio posts that serve as a template from which CNT emitters are fabricated. In addition to acting as a fabrication template, high aspect ratio posts can help elevate the CNT emitters from the surface, effectively reducing the electrostatic screening effect with respect to the surface. In some embodiments, posts with heights between 2 to 10 μm can be sufficient to significantly reduce the screening effect.

The substrate for a lateral-emission element can be high aspect-ratio Platinum (Pt) or Tungsten (W) pillars that can be fabricated using e-beam aided chemical vapor deposition (CVD). As illustrated in FIG. 6, W or Silicon (Si) knife-edges 620 can be ion-milled from a sharp W or Si tip. In general, ion-milling is less precise and produces knife-edge pillars as opposed to more precise deposited pillars, which can have diameters between 35-100 nm, lengths between 1-5 μm, and spacing between 1-10 μm. Refer to FIG. 7, for a photograph of Pt pillars 720, fabricated using e-beam assisted CVD, deposited on a sharp Si tip 710. In some embodiments, emitter arrays having more than 9 pillars can be formed using silicon micro-fabrication technology.

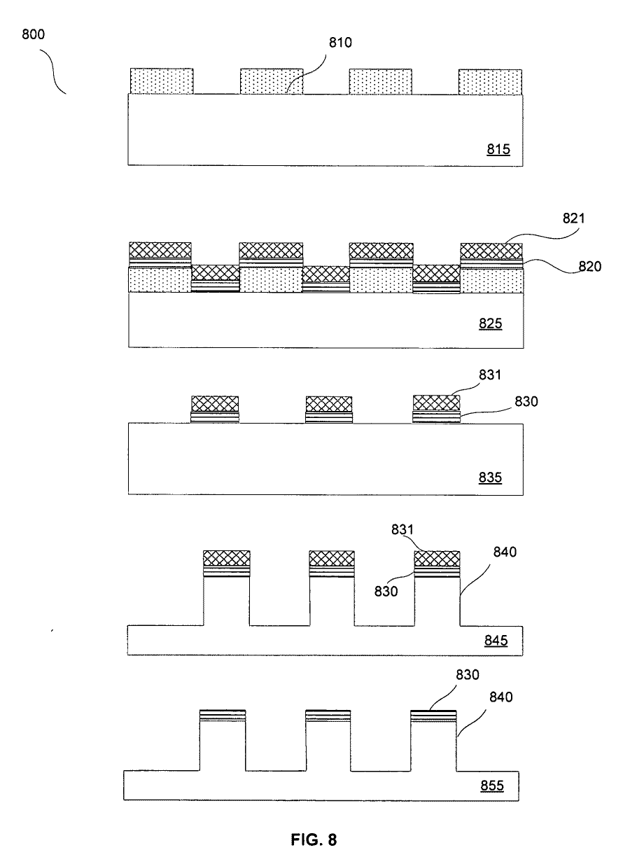

Referring next to FIG. 8 a diagram illustrating a series of stages in a large-scale micro-fabrication technique 800 is discussed according to various embodiments. Micro-fabrication of substrates can sometimes provide better control over post spacing, height, and cross-section size than other techniques. Si post arrays for the CNT emitters can be fabricated using a typical lift-off procedure using iron or nickel CNT catalyst as an etch mask. The post array can be lithographically patterned using electron beam lithography, optical lithography, or both. For example, electron beam lithography can be used to construct posts having diameters of less than about 500 nm, and optical lithography can be used to construct posts having diameters of greater than about 500 nm.

As illustrated by stage 815, a resist, for example an electron or photon beam resist, can be spun onto a silicon substrate, exposed, and developed to generate an array of substantially circular areas 810 on the silicon wafer. In various embodiments, post sizes, and consequently the sizes of the circular areas, can vary between about 20 nm and 1 μm, and the pitches can vary between about 1-10 μm.

At stage 825, a catalyst layer 820, for example a thin iron or nickel catalyst, can be evaporated onto the patterned substrate, and metal layer 821 deposited on top of catalyst layer 820. At stage 835, portions of catalyst layer 820 and metal layer 820 are “lifted off” to yield an array of catalyst dots 830, covered by metal dots 831.

At stage 845, areas not protected by metal dots 831 can be etched, for example by using a reactive ion etching process, to produce silicon posts 840. In some embodiments, this process can include using a Bosch or cryo deep silicon etch process.

At stage 855, metal dots 831 are removed, leaving posts 840 topped by catalyst dots 830, which can be used at a later time for growing laterally positioned carbon nanotubes.

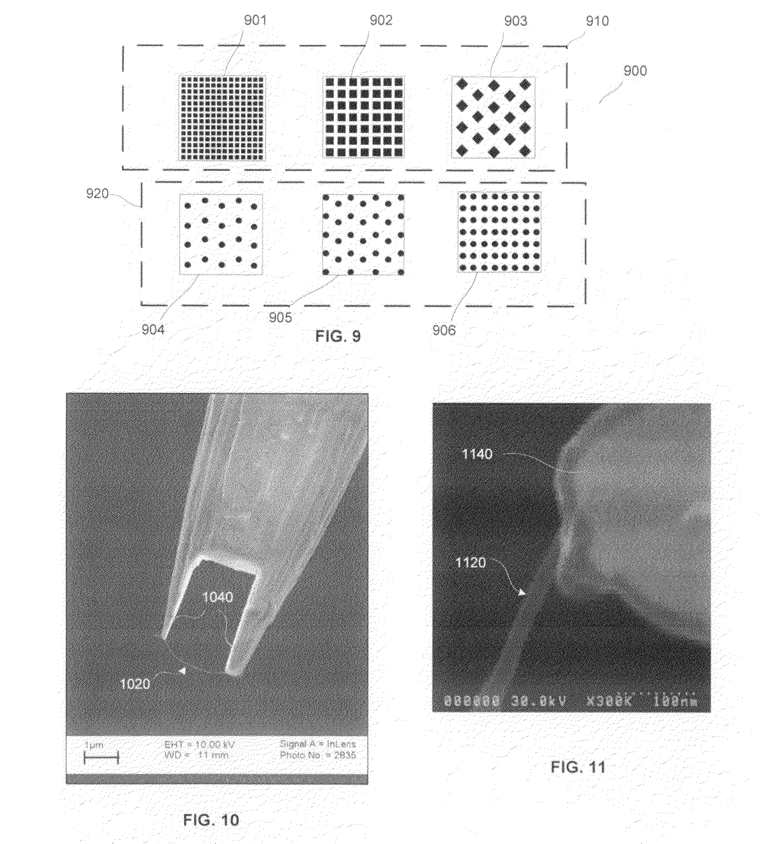

Referring next to FIG. 9, a diagram 900 schematically illustrates a top down view of six different post arrays 901-906 showing different pitch or size that may be fabricated using the above discussed process, or another suitable process. Arrays 901, 902, and 903, shown in group 910, illustrate different post sizes. Arrays 904, 905, and 906, shown in group 920, illustrate varying pitches, e.g. post spacing. In some embodiments, each of the posts is a sharp post, and the size and pitch can be selected taking into account various parameters such as screening effect desired field strength, expected yield, or the like.

Referring next to FIGS. 10 and 11, a manual CNT emitter fabrication processes is discussed according to embodiments of the present disclosure. A lateral-emission element including a single suspended carbon nanotube can be fabricated manually. For example, a dual-beam FIB tool or a SEM tool equipped with a NanoBot™ nanomanipulator, or another suitable micromaniupulator, can be used to manually suspend an individual CNT 1020 over two posts 1040. The ends of the CNT can be e-beam welded to the posts for better conductivity. FIG. 11 is an image of a CNT end 1120 welded to a post 1140 according to an embodiment of the present disclosure. The CNT 1020 illustrated in FIG. 10 was imaged after extensive field emission tests ranging up to 5 μA of current. CNT 1020 has a length of 1804 nm and a diameter of 18.2 nm. Although it can be practical in some cases to construct small lateral-emission arrays manually, e.g. arrays with 2-3 CNT emitters, using a scaleable CNT growth method to fabricate larger lateral emitter arrays will generally be more efficient.

A nanotube growth process according to various embodiments includes a catalyst deposition process and a thermal Chemical Vapor Deposition (CVD) process. CNTs grown in accordance with various embodiments of this process generally have multi walls, and diameters of less than about 10 nm. This growth process can produce single, horizontally suspended CNTs from an array of Si posts. In some instances, the growth process may produce more than one CNT spanning a particular gap between Si posts. In some embodiments, a CNT emitter growth yield of at least 50% should provide enough margin to achieve current emission targets of about 10 A/cm².

In various embodiments of the present disclosure, growth of horizontally suspended CNTs is accomplished using a precursor gas such as, ethylene, methane, or acetylene, at temperatures from 700 to 900° C., and catalyst such as Iron and Nickel, and using posts having ends sharper than typical cylindrical posts. Using sharp edges can contribute to the growth of sparse horizontally suspended CNTs, and reduce the probability of growing multiple nanotubes on the same posts.

In some embodiments, additional conditioning of the CNTs can be performed to increase available emission current from each individual emitter. In some embodiments, the work function of a CNT is lowered by coating the emitter with a low work-function material such as cesium (Cs), Zirconium Carbide (ZrC), Hafnium Carbide (HfC) and similar materials. In some embodiments, the width of the energy spread can also scale down with the work-function. Because the emission current depends on the work-function φ as φ^{3/2}/V, where V is the applied electric field, lowering of the work-function can have dramatic effects. It is known that Cs adsorption on a sharp W tip decreased the work-function from 4.5 eV to 1.6 eV while at the same time the energy spread decreased by a factor of 3. In some other embodiments coating a CNT with a metal layer, using a metal evaporator or using an electron beam induced chemical vapor deposition, increases the CNT bonding to a post and reducing the resistance between the CNT and the post.

An observed emission pattern from a lateral emitter is slightly oval, as opposed to a round emission pattern generally produced by vertical CNT emitters. In at least some embodiments, the shape of the field emission pattern from an array of lateral field emitters can be more or less oval than the pattern of a single CNT emitter. The overall shape and distribution of emissions from an array of lateral CNTs can vary with the placement of individual CNT emitters within the array.

Various embodiments disclosed herein can be used to implement devices such as CNT-based Scanning Electron Microscopy sources, and CNT-based X-ray sources having high current density, narrow energy spread, fast turn-on time and minimal heat generation. Some examples of X-ray implementations include X-ray metrology tools such as X-ray reflectance (XRR) and X-ray fluorescence (XRF) tools used to characterize thin films, single layers, multilayer stacks, high-k and low-k materials, metallic, dielectric, amorphous, poly-crystal and single-crystal films. Many industrial, medical and homeland security, law enforcement, and military applications requiring X-ray or Terahertz-ray sources can also benefit from some or all of the performance characteristics of lateral CNT emitters, as disclosed herein.

Benefits of some embodiments can include increased throughput due to the higher imaging speed made possible by high current density, and improved resolution due to the narrow energy spread of CNT lateral emitter-based X-ray sources. Other benefits can include fast turn-on time, minimal heat generation and compact size associated with lateral CNT-based devices.

In the preceding detailed description, reference has been made to the accompanying drawings that form a part hereof, and in which are shown by way of illustration specific embodiments in which the present invention may be practiced. These embodiments, and certain variants thereof, have been described in sufficient detail to enable those skilled in the art to practice embodiments of the present invention. It is to be understood that other suitable embodiments may be utilized and that logical, mechanical, chemical and electrical changes may be made without departing from the spirit or scope of such inventive disclosures. To avoid unnecessary detail, the description omits certain information known to those skilled in the art. The preceding detailed description is, therefore, not intended to be limited to the specific forms set forth herein, but on the contrary, it is intended to cover such alternatives, modifications, and equivalents, as can be reasonably included within the spirit and scope of the appended claims.

What is claimed is:

1. A device comprising:
a substrate having a protrusion thereon;
a plurality of posts located proximate to an end portion of the protrusion; and
at least one nanotube laterally connected between two posts of the plurality of posts.

2. The device of claim 1, wherein the end portion of the protrusion is less than about 10 microns wide.

3. The device of claim 1, wherein the plurality of posts are spaced less than about 10 microns apart.

4. The device of claim 1, wherein the plurality of posts are between about 20 nm and 1 micron in diameter.

5. The device of claim 1, wherein the plurality of posts are less than about 5 microns high.

6. The device of claim 1, wherein:
the protrusion comprises a wire having an end; and
the two posts comprise edge portions of the wire remaining after a center portion of the end of the wire has been removed.

7. The device of claim 1, wherein the nanotube has a diameter of less than about 20 nm.

8. The device of claim 1, further comprising:
a substrate having a plurality of protrusions thereon;
a plurality of posts located on uppermost portions of the plurality of protrusions; and
a plurality of nanotubes, each of which is laterally connected between at least two posts.

9. The device of claim 8 wherein the plurality of nanotubes are each positioned substantially the same distance above the surface of the substrate.

10. The device of claim 1, wherein a sidewall of the at least one nanotube forms an electrode.

11. The device of claim 10, wherein the at least one nanotube is configured to function as a cold cathode.

12. The device of claim 11, wherein the cold cathode is substantially parallel to an anode.

13. The device of claim 12, wherein the device is configured to emit electromagnetic radiation.

14. The device of claim 1, wherein the at least one nanotube includes a coating comprising a low work function material.

15. The device of claim 1, wherein the at least one nanotube comprises a previously grown nanotube positioned on the two posts.

16. The device of claim 1, wherein the two posts are configured to operate at different electrical potentials.

17. The device of claim 1, wherein the at least one nanotube comprises a nanotube grown between the two posts.

18. An emission device comprising:
a first electrode;
a second electrode;
the first electrode comprising
a substrate having a plurality of posts located thereon;
at least one nanotube laterally connected between the plurality of posts; and
the emission device configured to emit electrons primarily from a sidewall of the at least one nanotube.

19. The emission device of claim 18, wherein the plurality of posts are spaced less than about 10 microns apart.

20. The emission device of claim 18, wherein the plurality of posts are between about 20 nm and 1 micron in diameter.

21. The emission device of claim 18, wherein the plurality of posts are less than about 5 microns high.

22. The emission device of claim 18, wherein the nanotube has a diameter of less than about 20 nm.

23. The emission device of claim 18, further comprising a gate structure configured to extract electrons from the nanotube.

24. The emission device of claim 23, further comprising:
a bunching electrode,
a resonant cavity; and wherein
the emission device is configured to emit Terahertz-rays.

25. The emission device of claim 23, further comprising:
a bunching electrode,
a resonant cavity; and wherein
the emission device is configured to emit microwave radiation.

26. The emission device of claim 18, further comprising a plurality of laterally connected nanotubes forming an array.

27. The emission device of claim 26 wherein the plurality of laterally connected nanotubes are positioned at substantially the same distance above the surface of the substrate.

28. The emission device of claim 26 wherein the array is configured as an array of pixels for use in a display device.

29. The emission device of claim 26 wherein a plurality of the laterally connected nanotubes forming the array are configured to be individually controlled.

30. The emission device of claim 18, wherein at least two of the plurality of posts are laterally connected to a plurality of nanotubes.

31. The emission device of claim 18, wherein the at least one nanotube is configured as a cold cathode.

32. The emission device of claim 31, wherein the cold cathode is substantially parallel to an anode.

33. The emission device of claim 31, wherein the anode comprises a target anode configured to emit X-rays.

34. The emission device of claim 18, wherein the at least one nanotube includes a coating comprising a low work function material.

35. The emission device of claim 18, wherein the at least one nanotube comprises a previously grown nanotube positioned on the plurality of posts.

36. The emission device of claim 18, wherein the at least one nanotube comprises a nanotube grown between the plurality of posts.

37. A method comprising:
connecting an electron emission device to a power source, the electron emission device comprising:
at least one laterally positioned nanotube configured to operate as a first electrode;
a second electrode; and
applying a voltage to the electron emission device to generate electrons primarily from a sidewall of the laterally positioned nanotube.

38. The method of claim 37, wherein the electron emission device further comprises a gate structure coupled between the first electrode and the second electrode, the method further comprising using the gate to control an emission of electrons from the at least one laterally positioned nanotube.

39. The method of claim 38, further comprising generating a Terahertz frequency signal.

40. The method of claim 38, further comprising generating a microwave frequency signal.

41. The method of claim 37, wherein the electron emission device comprises an array of laterally positioned nanotubes.

42. The method of claim 37, further comprising using the at least one laterally positioned nanotube as a cold cathode.

43. The method of claim 42, further comprising using the at least one laterally positioned nanotube to generate X-rays.

44. The method of claim 37, wherein the at least one laterally positioned nanotube includes a coating comprising a low work function material.

45. The method of claim 37, wherein the at least one laterally positioned nanotube comprises a previously grown nanotube positioned on the plurality of posts.

46. The method of claim 37, wherein the at least one laterally positioned nanotube comprises a nanotube grown between the plurality of posts
